(19) United States
(12) Patent Application Publication
(10) Pub. No.: US 2026/0271249 A1
(43) Pub. Date: Sep. 10, 2026

(54) THERMAL REGULATION DEVICE FOR A COMPONENT, IN PARTICULAR A POWER ELECTRONIC MODULE

(71) Applicant: VALEO EAUTOMOTIVE GERMANY GMBH, Erlangen (DE)

(72) Inventors: Laurent MASSOL, Creteil Cedex (FR); Gabriel KOPP, Creteil Cedex (FR); Gregory HODEBOURG, Cergy Pontoise (FR); Arnoud SMIT, Erlangen (DE)

(73) Assignee: VALEO EAUTOMOTIVE GERMANY GMBH, Erlangen (DE)

(21) Appl. No.: 19/163,664

(22) PCT Filed: Mar. 14, 2024
(86) PCT No.: PCT/EP2024/056886

§ 371 Date: Sep. 9, 2025

(30) Foreign Application Priority Data
Mar. 15, 2023 (FR) FR2302403

(51) Int. Cl. H05K 7/20

(52) U.S. Cl. CPC H05K 7/20927; H05K 7/20254; H05K 7/20272

(57) ABSTRACT

A thermal regulation device for cooling and/or heating at least one component, the operation of which is temperature-sensitive. The component may be a power electronic module of an inverter. The thermal regulation device includes a stack of plates which are brazed together and form a sealed body in which at least one heat-transfer fluid circulation channel is arranged which extends through at least some of the plates in the stack.

The present invention relates to a thermal regulation device for cooling and/or heating at least one component of which the operation is sensitive to temperature, this component being in particular a power electronics module of an inverter.

Patent application WO2022248427 discloses a cooling structure comprising stacked plates forming a network of openings and chambers for the flow of a cooling fluid. This structure is placed in a pipe and this pipe is closed by a baseplate of a power electronics module. The cooling liquid flows through the meanderings within this structure.

The invention aims to provide a new type of thermal regulation device.

The invention thus relates to a thermal regulation device for cooling and/or heating at least one component of which the operation is sensitive to temperature, this component being in particular a power electronics module of an inverter, this thermal regulation device comprising a stack of plates which are brazed together and form a sealed body within which at least one circulation channel for heat-transfer fluid extending through at least some of the plates of the stack is formed.

The invention makes it possible to simplify the design and the manufacture of the thermal regulation device because multiple complex operations, such as friction stir welding (or FSW), machining and surface-finishing can be avoided. The invention also makes it possible to avoid using cast parts. The invention also makes it possible to avoid any direct hydraulic leakage path between the fluid inlet and the fluid outlet since the plates are brazed to one another and mutually leaktight. In addition, in the same environment and with the same overall size, the present invention makes it possible to maximize the exchanges of heat with the channel(s) within the stack because no volume is lost for example for the friction stir welding and on account of added parts. The invention also makes it possible to reduce the total mass of the exchanger with the same performance.

According to one of the aspects of the invention, the plates all have the same thickness within the stack.

In a variant, the plates have different thicknesses.

In particular, some plates have a first thickness and some of the other plates have a second thickness different from the first thickness.

The total number of plates may range between 5 and 20, in particular between 5 and 15 or between 5 and 10.

The plates may have a thickness of around 1 mm.

According to one of the aspects of the invention, the stack comprises a cover plate which is solid and defines at least one placement area for receiving a component, in particular a plurality of placement areas.

According to one of the aspects of the invention, this cover plate does not have a through-opening.

According to one of the aspects of the invention, this cover plate is at one of the ends of the stack.

According to one of the aspects of the invention, the stack comprises a baseplate which is provided with at least one through-opening forming, for the channel(s) of the stack, an inlet or an outlet for heat-transfer fluid. According to one of the aspects of the invention, the baseplate of the stack comprises both an inlet and an outlet for heat-transfer fluid.

According to one of the aspects of the invention, the fluid inlet and/or the fluid outlet have/has an elongate shape, for example each with two straight edges connected on each side to a circular arc.

According to one of the aspects of the invention, the thermal regulation device comprises at least one connector mounted on the baseplate and configured to fluidically connect the fluid outlet of the stack to an external discharge duct for heat-transfer fluid.

Thus, the baseplate bears two connectors, in particular crimped and brazed onto this baseplate.

According to one of the aspects of the invention, the connectors each have a neck.

According to one of the aspects of the invention, the plates have mechanical attachment shapes, in particular each in the form of a lug.

Other shapes are naturally conceivable. For example, the attachment shapes are formed inside a main periphery of the stack of plates.

According to one of the aspects of the invention, each mechanical attachment shape has an orifice which, when aligned with the respective orifices of the other plates, makes it possible to receive a fastening element, for example a tie rod, which holds the stack in place on a structural element of the vehicle.

According to one of the aspects of the invention, the connector has one or more mechanical attachment shapes, in particular each in the form of a lug.

According to one of the aspects of the invention, the plates of the stack each comprise a poka-yoke element configured to identify an orientation of the corresponding plate in relation to the other plates when the plates are being placed in relation to one another.

According to one of the aspects of the invention, the poka-yoke element is formed by a mechanical attachment shape which is offset, in particular in an axial direction, in relation to one or more other mechanical attachment shapes.

According to another of the aspects of the invention, the poka-yoke element is formed by a hole present on the stack for defining a visual positioning indicator.

According to another of the aspects of the invention, the poka-yoke element is formed by a recess present on the stack for defining a visual positioning indicator.

According to one of the aspects of the invention, the recess is in a corner of the stack. In a variant, the recess runs along a peripheral edge of the stack and may have steps.

According to one of the aspects of the invention, the stack of plates forms a network of channels within it that are configured to cool the component(s) placed on the cover plate.

According to one of the aspects of the invention, the network of channels may form one or more passes for fluid in contact with the cover plate.

According to one of the aspects of the invention, the plates all have the same periphery.

According to one of the aspects of the invention, the plates are based on aluminum, in particular are made of an aluminum alloy, for example of the 3003 type.

According to one of the aspects of the invention, at least one of the plates comprises an aluminum core and a braze material, this braze material being in particular of the 3003, 4343 or 4045 aluminum alloy type. The braze material may be on a lower face, an upper face or the two faces of the plate.

This braze material is referred to as “cladding”.

The invention also relates to an assembly comprising the thermal regulation device as specified above, and at least one power electronics module, in particular for an inverter, placed on a placement area of the thermal regulation device such that an exchange of heat is enabled between the heat transfer fluid circulating within the thermal regulation device and the power electronics module.

This placement area thus forms a heat exchange area.

According to one of the aspects of the invention, multiple power electronics modules are placed on different placement areas of the thermal regulation device, these areas being in particular all on a single main face of this thermal regulation device.

The invention also relates to a method for manufacturing a thermal regulation device for cooling and/or heating at least one component of which the operation is sensitive to temperature, this component being in particular a power electronics module of an inverter, this method comprising the following steps:
providing a stack of plates,
brazing the plates together to form a sealed body within which at least one circulation channel for heat-transfer fluid extending through at least some of the plates of the stack is formed.

According to one of the aspects of the invention, the braze material is initially in the form of a foil deposited on the aluminum core, or joined by co-laminating.

According to one of the aspects of the invention, the stacked plate(s) are initially provided with braze material on a single face or, in a variant, on the two faces.

According to one of the aspects of the invention, the stack is passed through a brazing furnace for carrying out the brazing, with or without pressurization.

According to one of the aspects of the invention, the stack comprises at least one weld bead produced around a periphery of this stack and possibly between the component placement areas, which are heat exchange areas, for each module, in particular by friction stir welding (FSW).

This weld bead makes it possible to enhance the leaktightness of the channel(s) within the stack.

Other features, details and advantages of the invention will become more clearly apparent on reading the description below and on studying several exemplary embodiments given by way of non-limiting indication with reference to the appended schematic drawings, in which:

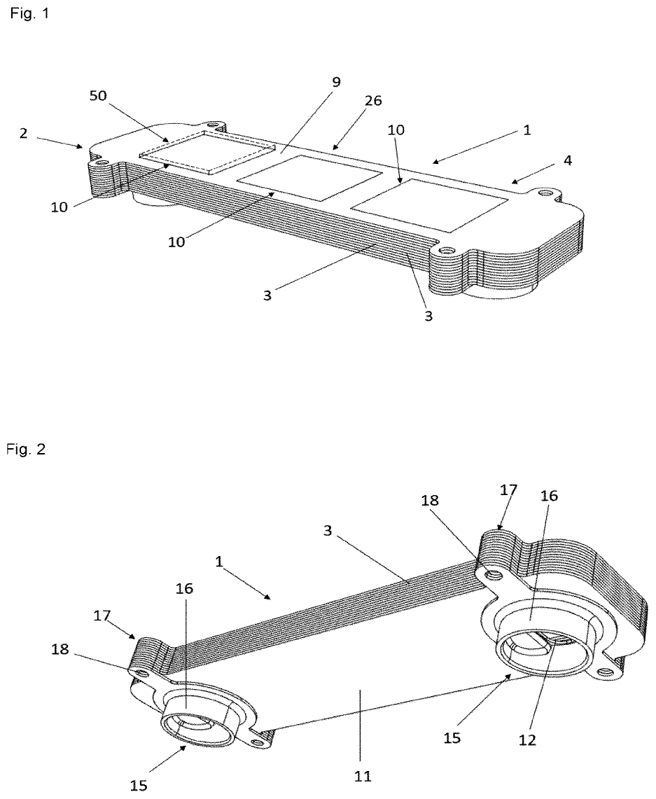

FIG. 1 is a perspective representation, from above, of a thermal regulation device according to one exemplary embodiment of the invention;

FIG. 2 is a profile view, from above, of the thermal regulation device in FIG. 1;

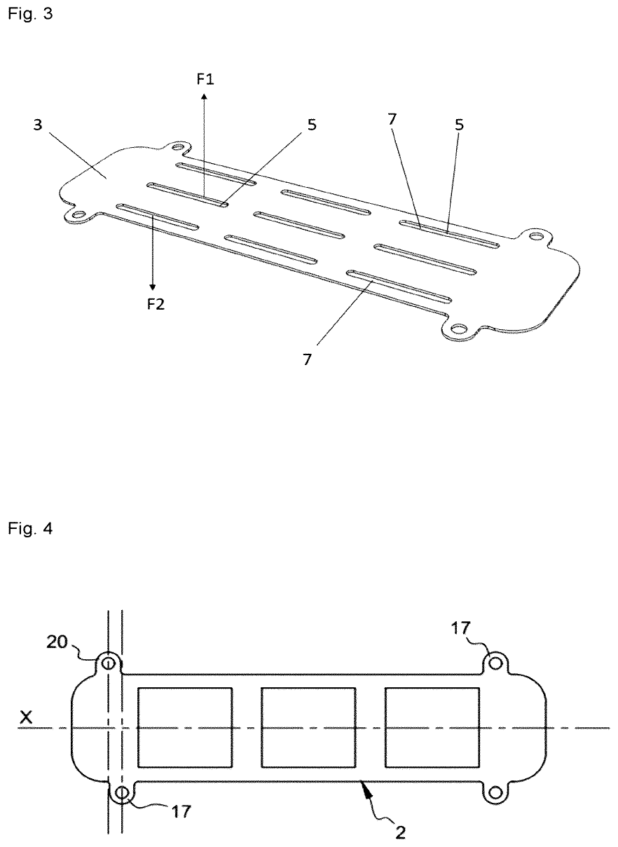

FIG. 3 is a perspective representation of a plate of the thermal regulation device illustrated in FIGS. 1 and 2;

FIG. 4 is a representation of a stack of plates according to one example of the invention, with one type of poka-yoke element;

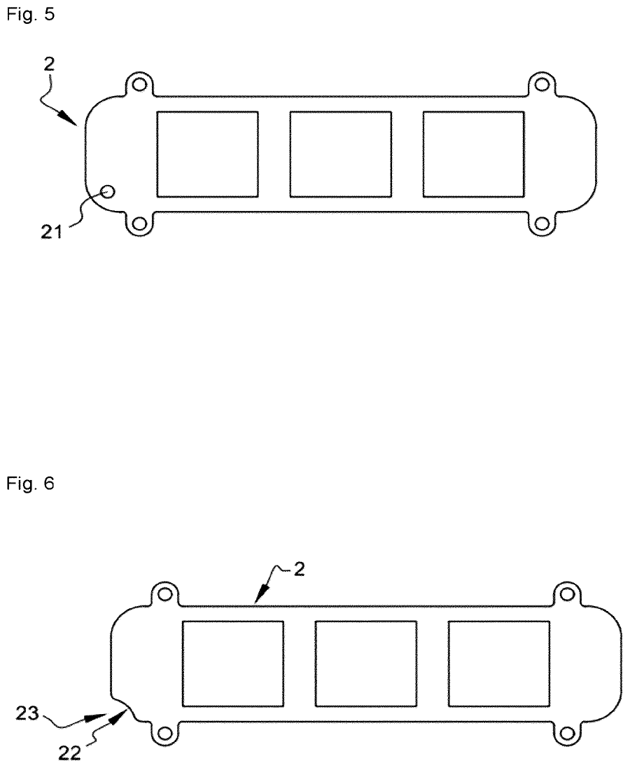

FIG. 5 is a representation of a stack of plates according to another example of the invention, with another type of poka-yoke element;

FIG. 6 is a representation of a stack of plates according to another example of the invention, with another type of poka-yoke element;

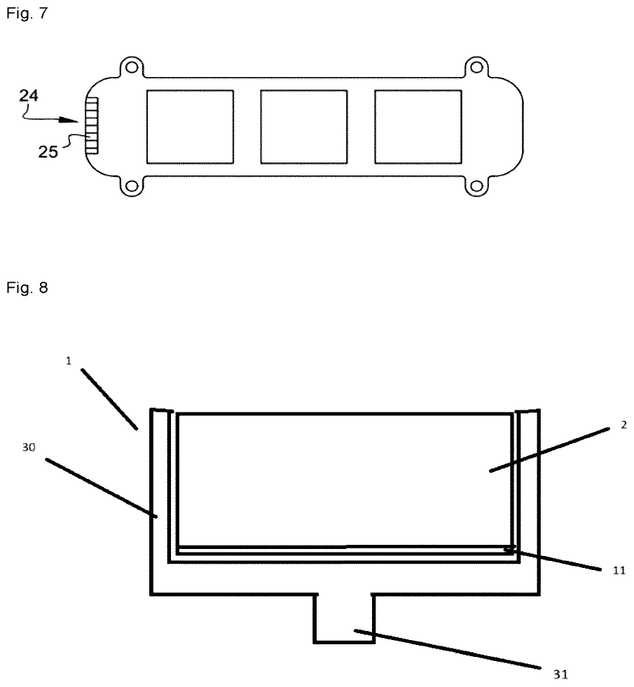

FIG. 7 is a representation of a stack of plates according to another example of the invention, with another type of poka-yoke element.

The features, variants and various embodiments of the invention may be combined with one another, in various combinations, as long as they are not mutually incompatible or mutually exclusive. It will be possible, in particular, to imagine variants of the invention that comprise only a selection of the features described below, in isolation from the other features described, provided that this selection of features is sufficient to confer a technical advantage and/or to distinguish the invention from the prior art.

FIGS. 1 and 2 show a thermal regulation device 1 for cooling multiple power electronics modules 50 of an inverter. In this case, there are three power electronics modules 50 (a single one of which is shown in dotted lines).

The thermal regulation device 1 comprises a stack 2 of plates 3 which are brazed together and form a sealed body 4 within which circulation channels 5 for heat-transfer fluid, for example glycol water, extending through some of the plates 3 of the stack 2 is formed.

These channels 5 are for example defined by apertures 7 in some plates 3, these apertures 7 forming the channels 5 in the direction of the stack of plates 3. These channels 5 may allow the fluid to circulate in a direction F1 and in a direction F2 to obtain the desired passes for fluid, as can be seen in FIG. 3.

The plates 3 all have the same thickness within the stack 2. In a variant, the plates have different thicknesses.

The stack 2 comprises a cover plate 9 which is solid and defines placement areas 10 for each receiving one power electronics module 50.

This cover plate 9 does not have a through-opening and is located at one of the ends of the stack 2.

The stack 2 further comprises a baseplate 11 which is provided with through-openings 12 forming, for the channels 5 of the stack, an inlet or an outlet for heat-transfer fluid.

These through-openings 12 have an elongate shape, for example each with two straight edges connected on each side to a circular arc.

The thermal regulation device 1 comprises two connectors 15 mounted, in particular by crimping and brazing, on the baseplate 11 and each configured to fluidically connect the fluid inlet of the stack 2 to an external supply pipe (not shown) for heat-transfer fluid.

The connectors 15 each have a neck 16.

The plates 3, 9 and 11 have mechanical attachment shapes 17, each in the form of a lug in the example described.

Other shapes are naturally conceivable. For example, the attachment shapes are formed inside a main periphery of the stack of plates.

Each mechanical attachment shape 17 has an orifice 18 which, when aligned with the respective orifices of the other plates, makes it possible to receive a fastening element, for example a tie rod, which holds the stack 2 in place on a structural element of the vehicle.

The connector 15 has mechanical attachment shapes 17 in the manner of the plates of the stack 2.

As illustrated in the examples in FIGS. 4 to 7, the plates 3 of the stack 2 may each comprise a poka-yoke element configured to identify an orientation of the corresponding plate in relation to the other plates 3 when the plates are being placed in relation to one another.

In the example in FIG. 4, the poka-yoke element is formed by a mechanical attachment shape 20 which is offset, in an axial direction X, in relation to other mechanical attachment shapes 17.

In the example in FIG. 5, the poka-yoke element is formed by a hole 21 present on the stack 2 for defining a visual positioning indicator.

In the example in FIG. 6, the poka-yoke element is formed by a recess 22 present on the stack for defining a visual positioning indicator. This recess 22 is in a corner 23 of the stack 2. In a variant, as illustrated in FIG. 7, the recess 24 runs along a peripheral edge of the stack 2 and may have steps 25.

The stack 2 of plates forms a network of channels 5 within it that are configured to cool the components placed on the cover plate 9.

The network of channels 5 may form one or more passes for fluid in contact with the cover plate.

The plates 3 all have the same periphery, which is rectangular overall with rounded corners 23.

The plates 3 are made of an aluminum alloy, for example of the 3003 type.

The plates 3 comprise an aluminum core and a braze material, this braze material being in particular of the 3003, 4343 or 4045 aluminum alloy type. The braze material may be on a lower face, an upper face or the two faces of the plate.

This braze material is referred to as “cladding”.

The thermal regulation device 1 and the modules 50 laid on top form an assembly 60. The placement areas 10 are all on a single main face 26 of the thermal regulation device 1.

The thermal regulation device 1 is manufactured by a method comprising the following steps:
providing plates 3,
brazing the plates together to form the sealed body 4, in a brazing furnace for carrying out the brazing, with or without pressurization.

The plates are preferably all brazed at the same time so that they only pass through the furnace once.

The braze material is initially in the form of a foil deposited on the aluminum core, or joined by co-laminating.

The stack 2 may comprise a weld bead produced around a periphery of this stack and possibly between the component placement areas 10, which are heat exchange areas, for each module, in particular by friction stir welding (FSW).

1. A thermal regulation device for cooling and/or heating at least one component of which the operation is sensitive to temperature, this component being in particular a power electronics module of an inverter, this thermal regulation device comprising
a stack of plates which are brazed together and form a sealed body within which at least one circulation channel for heat-transfer fluid extending through at least some of the plates of the stack is formed.

2. The thermal regulation device as claimed in the claim 1, wherein the stack comprises a cover plate which is solid and defines at least one placement area for receiving a component.

3. The thermal regulation device according to claim 1, wherein the stack comprises a baseplate which is provided with at least one through-opening forming, for the channel(s) of the stack, an inlet or an outlet for heat-transfer fluid.

4. The thermal regulation device as claimed in claim 1,
wherein the thermal regulation device comprises at least one connector mounted on the baseplate and configured to fluidically connect the fluid outlet of the stack to an external discharge duct for heat-transfer fluid.

5. The thermal regulation device as claimed in claim 1, wherein the plates have mechanical attachment shapes, in particular each in the form of a lug.

6. The thermal regulation device as claimed in claim 1, wherein the plates of the stack each comprise a poka-yoke element configured to identify an orientation of the corresponding plate in relation to the other plates when the plates are being placed in relation to one another.

7. The thermal regulation device as claimed in claim 1, wherein the plates are based on aluminum, in particular are made of an aluminum alloy, for example of the 3003 type.

8. An assembly comprising the thermal regulation device as claimed in claim 1, and at least one power electronics module in particular for an inverter, placed on a placement area of the thermal regulation device such that an exchange of heat is enabled between the heat transfer fluid circulating within the thermal regulation device and the power electronics module.

9. A method for manufacturing a thermal regulation device for cooling and/or heating at least one component of which the operation is sensitive to temperature, this component being in particular a power electronics module of an inverter, this method comprising the following steps:
providing a stack of plates,
brazing the plates together to form a sealed body within which at least one circulation channel for heat-transfer fluid extending through at least some of the plates of the stack is formed.

10. The method as claimed in claim 9, wherein the stack is passed through a brazing furnace for carrying out the brazing, with or without pressurization.

11. The thermal regulation device according to claim 2, wherein the stack comprises a baseplate which is provided with at least one through-opening forming, for the channel(s) of the stack, an inlet or an outlet for heat-transfer fluid.

12. The thermal regulation device as claimed in claim 2,
wherein the thermal regulation device comprises at least one connector mounted on the baseplate and configured to fluidically connect the fluid outlet of the stack to an external discharge duct for heat-transfer fluid.

13. The thermal regulation device as claimed in claim 2, wherein the plates have mechanical attachment shapes, in particular each in the form of a lug.

14. The thermal regulation device as claimed in claim 2, wherein the plates of the stack each comprise a poka-yoke element configured to identify an orientation of the corresponding plate in relation to the other plates when the plates are being placed in relation to one another.

15. The thermal regulation device as claimed in claim 2, wherein the plates are based on aluminum, in particular are made of an aluminum alloy, for example of the 3003 type.

16. An assembly comprising the thermal regulation device as claimed in claim 2, and at least one power electronics module, in particular for an inverter, placed on a placement area of the thermal regulation device such that an exchange of heat is enabled between the heat transfer fluid circulating within the thermal regulation device and the power electronics module.

17. The thermal regulation device as claimed in claim 3,
wherein the thermal regulation device comprises at least one connector mounted on the baseplate and configured to fluidically connect the fluid outlet of the stack to an external discharge duct for heat-transfer fluid.

18. The thermal regulation device as claimed in claim 3, wherein the plates have mechanical attachment shapes, in particular each in the form of a lug.

19. The thermal regulation device as claimed in claim 3, wherein the plates of the stack each comprise a poka-yoke element configured to identify an orientation of the corresponding plate in relation to the other plates when the plates are being placed in relation to one another.

20. The thermal regulation device as claimed in claim 3, wherein the plates are based on aluminum, in particular are made of an aluminum alloy, for example of the 3003 type.
